(19) United States
(12) Patent Application Publication
(10) Pub. No.: US 2024/0306435 A1
(43) Pub. Date: Sep. 12, 2024

(54) MOTHERBOARD FOR DISPLAY DEVICE AND DISPLAY DEVICE

(71) Applicant: Japan Display Inc., Tokyo (JP)

(72) Inventors: Hiroshi TABATAKE, Tokyo (JP); Sho YANAGISAWA, Tokyo (JP)

(73) Assignee: Japan Display Inc., Tokyo (JP)

(21) Appl. No.: 18/599,269

(22) Filed: Mar. 8, 2024

(30) Foreign Application Priority Data
Mar. 10, 2023 (JP) 2023-037314

(51) Int. Cl. H10K 59/122; G09G 3/3225

(52) U.S. Cl. CPC H10K 59/122; G09G 3/3225; G09G 2300/0842

(57) ABSTRACT

According to one embodiment, a motherboard for display device includes a plurality of panel portions each including a display area where a plurality of display elements are arranged, a margin area around the plurality of panel portions and an alignment mark arranged in the margin area. The panel portion includes an organic insulating layer, a lower electrode, an upper electrode, and an organic layer that emits light in accordance with a potential difference between the lower electrode and the upper electrode. The organic insulating layer extends from the display area to the margin area. The organic insulating layer arranged in the margin area and an inorganic insulating layer covering the organic insulating layer are arranged above the alignment mark.

### CROSS-REFERENCE TO RELATED APPLICATION

This application is based upon and claims the benefit of priority from Japanese Patent Application No. 2023-037314, filed Mar. 10, 2023, the entire contents of which are incorporated herein by reference.

### FIELD

Embodiments described herein relate generally to a motherboard for display device, and a display device.

### BACKGROUND

Recently, display devices with organic light emitting diodes (OLED) applied as display elements have been put into practical use. This display element comprises a lower electrode, an organic layer covering the lower electrode, and an upper electrode covering the organic layer.

In manufacturing the display device, a plurality of panel portions including a display area where a number of display elements are arranged are formed on a large motherboard. A display panel, which is a main element of the display device, is manufactured by cutting each panel portion from this large motherboard.

In such a manufacturing process, alignment marks for alignment are formed on the motherboard and each panel portion. The elements constituting each panel portion are arranged in precise positions, based on these alignment marks. However, the alignment marks may be lost or smudged in the process of forming the elements constituting each panel portion (e.g., patterning or the like). If the alignment marks are lost or smudged, positioning cannot be accurately performed.

### BRIEF DESCRIPTION OF THE DRAWINGS

FIG. 1 is a view showing a configuration example of a display device according to one of embodiments.

FIG. 2 is a view showing an example of a layout of sub-pixels.

FIG. 3 is a schematic cross-sectional view showing the display device along line III-III in FIG. 2.

FIG. 4 is a schematic plan view showing a motherboard according to the embodiment.

FIG. 5 is a schematic plan view showing an alignment mark according to the embodiment.

FIG. 6 is a schematic plan view showing the alignment mark according to the embodiment.

FIG. 7 is a flowchart showing an example of a method of manufacturing the motherboard and the display device according to the embodiment.

FIG. 8A is a schematic cross-sectional view showing a display area on the motherboard in the process of manufacturing.

FIG. 8B is a schematic cross-sectional view showing a margin area on the motherboard in the process of manufacturing.

FIG. 9A is a schematic cross-sectional view showing the display area, illustrating a process following FIG. 8A.

FIG. 9B is a schematic cross-sectional view showing the margin area, illustrating a process following FIG. 8B.

FIG. 10A is a schematic cross-sectional view showing the display area, illustrating a process following FIG. 9A.

FIG. 10B is a schematic cross-sectional view showing the margin area, illustrating a process following FIG. 9B.

FIG. 11A is a schematic cross-sectional view showing the display area, illustrating a process following FIG. 10A.

FIG. 11B is a schematic cross-sectional view showing the margin area, illustrating a process following FIG. 10B.

FIG. 12A is a schematic cross-sectional view showing the display area, illustrating a process following FIG. 11A.

FIG. 12B is a schematic cross-sectional view showing the margin area, illustrating a process following FIG. 11B.

FIG. 13A is a schematic cross-sectional view showing the display area, illustrating a process following FIG. 12A.

FIG. 13B is a schematic cross-sectional view showing the margin area, illustrating a process following FIG. 12B.

FIG. 14A is a schematic cross-sectional view showing the display area, illustrating a process following FIG. 13A.

FIG. 14B is a schematic cross-sectional view showing the margin area, illustrating a process following FIG. 13B.

FIG. 15A is a schematic cross-sectional view showing the display area, illustrating a process following FIG. 14A.

FIG. 15B is a schematic cross-sectional view showing the margin area, illustrating a process following FIG. 14B.

FIG. 16 is a schematic cross-sectional view showing a margin area on a motherboard according to a comparative example.

### DETAILED DESCRIPTION

In general, according to one embodiment, a motherboard for display device includes a plurality of panel portions each including a display area where a plurality of display elements are arranged, a margin area around the plurality of panel portions, and an alignment mark arranged in the margin area. The panel portion includes an organic insulating layer, a lower electrode arranged above the organic insulating layer, an upper electrode opposed to the lower electrode, and an organic layer arranged between the lower electrode and the upper electrode to emit light in accordance with a potential difference between the lower electrode and the upper electrode. The organic insulating layer extends from the display area to the margin area. The organic insulating layer arranged in the margin area and an inorganic insulating layer covering the organic insulating layer are arranged above the alignment mark.

According to another embodiment, a display device includes a display area where a plurality of display elements are arranged, a surrounding area around the display area, and an alignment mark arranged in the surrounding area. An organic insulating layer, a lower electrode arranged above the organic insulating layer, an upper electrode opposed to the lower electrode, and an organic layer arranged between the lower electrode and the upper electrode to emit light in accordance with a potential difference between the lower electrode and the upper electrode, are provided in the display area. The organic insulating layer extends from the display area to the surrounding area. The organic insulating layer arranged in the surrounding area and an inorganic insulating layer covering the organic insulating layer are arranged above the alignment mark.

Embodiments will be described hereinafter with reference to the accompanying drawings. The disclosure is merely an example and is not limited by contents described in the embodiments described below. Modification which is easily conceivable by a person of ordinary skill in the art comes within the scope of the disclosure as a matter of course. In order to make the description clearer, the sizes, shapes and the like of the respective parts may be changed and illustrated schematically in the drawings as compared with those in an accurate representation. Constituent elements corresponding to each other in a plurality of drawings are denoted by like reference numerals and their detailed descriptions may be omitted unless necessary.

In the figures, an X-axis, a Y-axis and a Z-axis orthogonal to each other are described to facilitate understanding as needed. A direction along the X-axis is referred to as a first direction, a direction along the Y-axis is referred to as a second direction, and a direction along the Z-axis is referred to as a third direction. The third direction Z is a normal to a plane including the first direction X and the second direction Y. In addition, viewing various elements parallel to the third direction Z is referred to as plan view.

The display device of this embodiment is an organic electroluminescent display device comprising an organic light emitting diode (OLED) as a display element, and can be mounted on various electronic devices such as televisions, personal computers, vehicle-mounted devices, tablet terminals, smartphones, mobile phones, and wearable terminals.

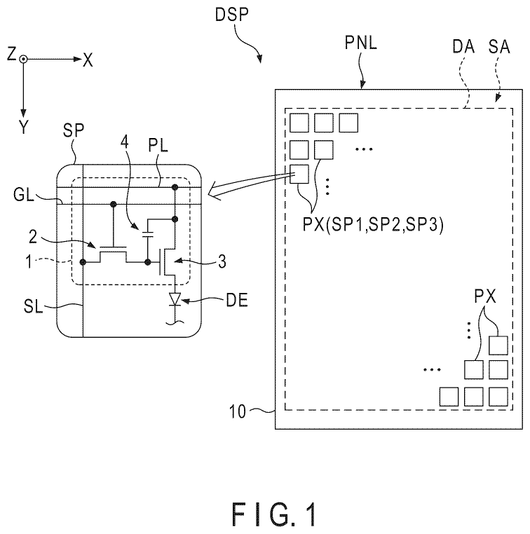

FIG. 1 is a view showing a configuration example of a display device DSP according to the embodiment. The display device DSP comprises a display panel PNL including an insulating substrate 10. The display panel PNL has a display area DA on which an image is displayed and a surrounding area SA located around the display area DA. The substrate 10 may be glass or a flexible resin film.

In the embodiment, the shape of the substrate 10 in plan view is a rectangular shape. However, the shape of the substrate 10 in plan view is not limited to a rectangular shape, but may be any other shape such as a square, a circle or an ellipse.

The display area DA includes a plurality of pixels PX arrayed in a matrix in the first direction X and the second direction Y. Each of the pixels PX includes a plurality of sub-pixels SP. In one example, each pixel PX includes a blue sub-pixel SP1, a green sub-pixel SP2, and a red sub-pixel SP3. Incidentally, the pixel PX may include sub-pixels SP of other colors such as a white color together with the sub-pixels SP1, SP2, and SP3 or instead of any of the sub-pixels SP1, SP2, and SP3.

The sub-pixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either of a source electrode and a drain electrode of the pixel switch 2 is connected to a signal line SL, and the other is connected to a gate electrode of the drive transistor 3 and the capacitor 4. In the drive transistor 3, either of the source electrode and the drain electrode is connected to the power line PL and the capacitor 4, and the other is connected to the display element DE.

Incidentally, the configuration of the pixel circuit 1 is not limited to the example shown in the drawing. For example, the pixel circuit 1 may comprise more thin-film transistors and more capacitors.

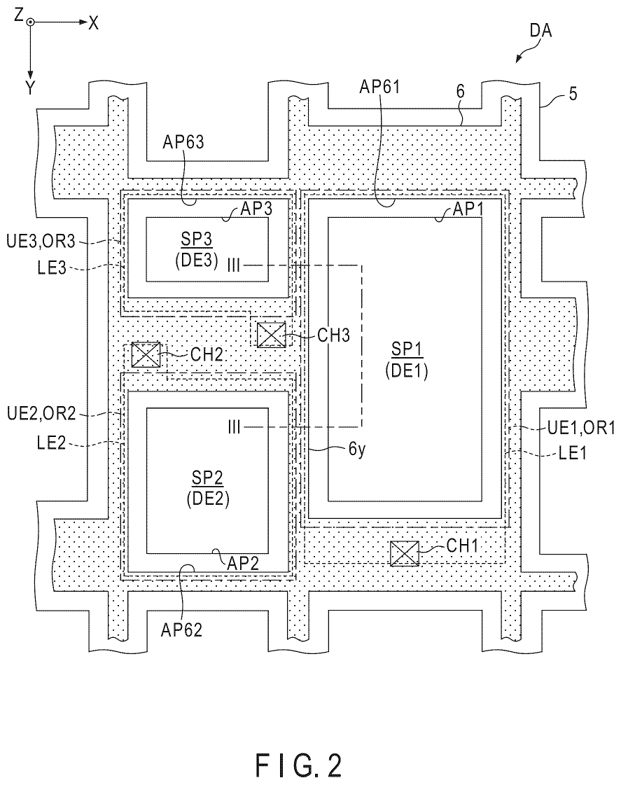

FIG. 2 is a schematic plan view showing an example of a layout of the sub-pixels SP1, SP2, and SP3. In the example of FIG. 2, each of the sub-pixels SP2 and SP3 is arranged with the sub-pixel SP1 in the first direction X. Furthermore, the sub-pixel SP2 and the sub-pixel SP3 are arranged in the second direction Y.

When the sub-pixels SP1, SP2, and SP3 are arranged in such a layout, a row in which the sub-pixels SP2 and SP3 are alternately arranged in the second direction Y and a row in which a plurality of sub-pixels SP1 are repeatedly arranged in the second direction Y are formed in the display area DA. These rows are alternately arranged in the first direction X. Incidentally, the layout of the sub-pixels SP1, SP2, and SP3 is not limited to the example in FIG. 2.

A rib 5 is arranged in the display area DA. The rib 5 includes pixel apertures AP1, AP2, and AP3 in the respective sub-pixels SP1, SP2, and SP3. In the example shown in FIG. 2, the pixel aperture AP1 is larger than the pixel aperture AP2, and the pixel aperture AP2 is larger than the pixel aperture AP3.

The sub-pixel SP1 comprises a lower electrode LE1, an upper electrode UE1, and an organic layer OR1 each overlapping with the pixel aperture AP1. The sub-pixel SP2 comprises a lower electrode LE2, an upper electrode UE2, and an organic layer OR2 each overlapping with the pixel aperture AP2. The sub-pixel SP3 comprises a lower electrode LE3, an upper electrode UE3, and an organic layer OR3 each overlapping with the pixel aperture AP3.

The parts of the lower electrode LE1, the upper electrode UE1, and the organic layer OR1, which overlap with the pixel aperture AP1, constitute the display element DE1 of the sub-pixel SP1. The parts of the lower electrode LE2, the upper electrode UE2, and the organic layer OR2, which overlap with the pixel aperture AP2, constitute the display element DE2 of the sub-pixel SP2. The parts of the lower electrode LE3, the upper electrode UE3, and the organic layer OR3, which overlap with the pixel aperture AP3, constitute the display element DE3 of the sub-pixel SP3. The display elements DE1, DE2, and DE3 may further include a cap layer to be described below. The rib 5 surrounds each of these display elements DE1, DE2, and DE 3.

The lower electrode LE1 is connected to the pixel circuit 1 of the sub-pixel SP1 (see FIG. 1) through a contact hole CH1. The lower electrode LE2 is connected to the pixel circuit 1 of the sub-pixel SP2 through a contact hole CH2. The lower electrode LE3 is connected to the pixel circuit 1 of the sub-pixel SP3 through the contact hole CH3.

A partition 6 is arranged on the rib 5. The partition 6 entirely overlaps with the rib 5 and has the same planar shape as the rib 5. In other words, the partition 6 includes apertures AP61, AP62, and AP63 in the respective sub-pixels SP1, SP2, and SP3. From another viewpoint, the rib 5 and the partition 6 are arranged between the display elements DE1, DE2, and DE3 and have a grating shape in plan view.

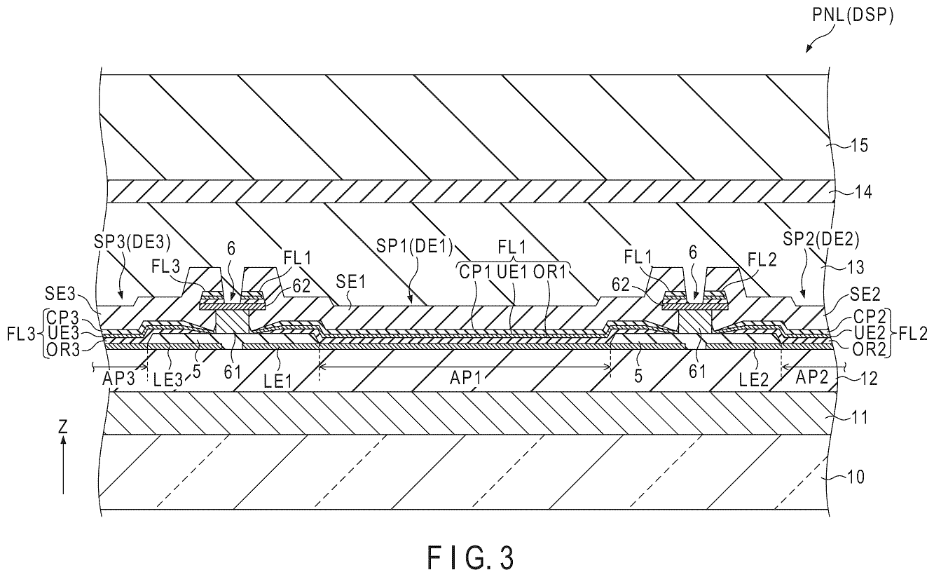

FIG. 3 is a schematic cross-sectional view showing the display panel PNL along line III-III in FIG. 2. A circuit layer 11 is arranged on the above-described substrate 10. The circuit layer 11 includes various circuits and lines such as the pixel circuits 1, the scanning lines GL, the signal lines SL and the power lines PL shown in FIG. 1.

The circuit layer 11 is covered with an organic insulating layer 12. The organic insulating layer 12 functions as a planarization film for planarizing uneven parts generated by the circuit layer 11. Although not shown in the cross section of FIG. 3, the above-described contact holes CH1, CH2, and CH3 are provided in the organic insulating layer 12.

The lower electrodes LE1, LE2, and LE3 are arranged on the organic insulating layer 12. The rib 5 is arranged on the organic insulating layer 12 and the lower electrodes LE1, LE 2, and LE3. End parts of the lower electrodes LE1, LE2, and LE3 are covered with the rib 5.

The partition 6 includes a lower portion 61 which is arranged on the rib 5 and is conductive and an upper portion 62 which is arranged on the lower portion 61. The upper portion 62 has a width greater than the lower portion 61. As a result, both the end parts of the upper portion 62 protrude beyond the side surfaces of the lower portion 61. This shape of the partition 6 is referred to as overhanging.

The organic layer OR1 covers the lower electrode LE1 through the pixel aperture AP1. The upper electrode UE1 covers the organic layer OR1 and is opposed to the lower electrode LE1. The organic layer OR2 covers the lower electrode LE2 through the pixel aperture AP2. The upper electrode UE2 covers the organic layer OR2 and is opposed to the lower electrode LE2. The organic layer OR3 covers the lower electrode LE3 through the pixel aperture AP3. The upper electrode UE3 covers the organic layer OR3 and is opposed to the lower electrode LE3. The upper electrodes UE1, UE2, and UE3 are in contact with side surfaces of the lower portion 61 of the partition 6.

In the example shown in FIG. 3, a cap layer CP1 is arranged on the upper electrode UE1, a cap layer CP2 is arranged on the upper electrode UE2, and a cap layer CP3 is arranged on the upper electrode UE3. The cap layers CP1, CP2, and CP3 have a role as optical adjustment layers for improving the outcoupling efficiency of the light emitted from the organic layers OR1, OR2, and OR3.

In the following descriptions, a multilayer body including the organic layer OR1, the upper electrode UE1, and the cap layer CP1 is referred to as a multilayer film FL1, a multilayer body including the organic layer OR2, the upper electrode UE2, and the cap layer CP2 is referred to as a multilayer film FL2, and a multilayer body including the organic layer OR3, the upper electrode UE3, and the cap layer CP3 is referred to as a multilayer film FL3.

A part of the multilayer film FL1 is located on the upper portion 62. This part is separated from a portion of the multilayer film FL1, which is located under the partition 6 (i.e., a portion constituting the display element DE1). Similarly, a part of the multilayer film FL2 is located on the upper portion 62, and this part is separated from a portion of the multilayer film FL2, which is located under the partition 6 (i.e., a portion constituting the display element DE2). Furthermore, a part of the multilayer film FL3 is located on the upper portion 62, and this part is separated from a portion of the multilayer film FL3, which is located under the partition 6 (i.e., a portion constituting the display element DE3).

Sealing layers SE1, SE2 and SE3 are provided in the sub-pixels SP1, SP2 and SP3, respectively. The sealing layer SE1 continuously covers the multilayer film FL1, and the partition 6 around the sub-pixel SP1. The sealing layer SE2 continuously covers the multilayer film FL2, and the partition 6 around the sub-pixel SP2. The sealing layer SE3 continuously covers the multilayer film FL3, and the partition 6 around the sub-pixel SP3.

In the example shown in FIG. 3, the multilayer film FL1 and the sealing layer SE1 on the partition 6 between the sub-pixels SP1 and SP2 are separated from the multilayer film FL2 and the sealing layer SE2 on the partition 6. In addition, the multilayer film FL1 and the sealing layer SE1 on the partition 6 between the sub-pixels SP1 and SP3 are separated from the multilayer film FL3 and the sealing layer SE3 on the partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are provided continuously on a whole body of at least the display area DA, and partially extend to the surrounding area SA.

A cover member such as a polarizer, a touch panel, a protective film or a cover glass may be further arranged above the resin layer 15. Such a cover member may be adhered to the resin layer 15 via, for example, an adhesive layer such as an optical clear adhesive (OCA).

The organic insulating layer 12 is formed of an organic insulating material. The rib 5 and the sealing layers 14, SE1, SE2, and SE3 are formed of an inorganic insulating material such as silicon nitride (SiNx), silicon oxide (SiOx), silicon oxynitride (SiON) or aluminum oxide (Al₂O₃). In one example, the rib 5 is formed of silicon oxynitride and the sealing layers 14, SE1, SE2, and SE3 are formed of silicon nitride. The resin layers 13 and 15 are formed of, for example, a resin material (organic insulating material) such as epoxy resin or acrylic resin.

The lower electrodes LE1, LE2, and LE3 include, for example, a reflective layer formed of silver (Ag) and a pair of conductive oxide layers that cover upper and lower surfaces of this reflective layer, respectively. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metal material such as an alloy (MgAg) of magnesium and silver. For example, the lower electrodes LE1, LE2, and LE3 correspond to anodes, and the upper electrodes UE1, UE2, and UE3 correspond to cathodes.

Each of the organic layers OR1, OR2, and OR3 has a multilayer structure of, for example, a hole injection layer, a hole transport layer, an electron blocking layer, a light emitting layer, a hole blocking layer, an electron-transport layer, and an electron injection layer. The organic layers OR1, OR2, and OR3 may have a so-called tandem structure including a plurality of light emitting layers.

The cap layers CP1, CP2 and CP3 has, for example, a multilayer structure in which a plurality of transparent thin films are stacked. The plurality of thin films may include a thin film formed of an inorganic material and a thin film formed of an organic material. In addition, the plurality of thin films have refractive indices different from each other. The materials of the thin films are different from the materials of the upper electrodes UE1, UE2 and UE3 and are also different from the materials of the sealing layers SE1, SE2 and SE3. Incidentally, at least one of the cap layers CP1, CP2, and CP3 may be omitted.

The lower portion 61 of the partition 6 is formed of, for example, aluminum. The lower portion 61 may be formed of an aluminum alloy such as aluminum-neodymium (AlNd), aluminum-yttrium alloy (AlY) or aluminum-silicon alloy (AlSi) or may have a multilayer structure of an aluminum layer and an aluminum alloy layer. Furthermore, the lower portion 61 may include a bottom layer formed of a metal material different from aluminum or an aluminum alloy, under the aluminum layer or the aluminum alloy layer. For example, molybdenum (Mo), titanium nitride (TiN), molybdenum-tungsten alloy (MoW) or molybdenum-niobium alloy (MoNb) can be used as the metal material forming such a bottom layer.

The upper portion 62 of the partition 6 has, for example, a multilayer structure of a lower layer formed of a metal material and an upper layer formed of a conductive oxide. For example, titanium, titanium nitride, molybdenum, tungsten, a molybdenum-tungsten alloy or a molybdenum-niobium alloy can be used as the metal material forming the lower layer. For example, ITO or IZO can be used as the conductive oxide forming the upper layer. Incidentally, the upper portion 62 may have a single-layer structure of a metal material.

A common voltage is supplied to the partition 6. This common voltage is supplied to each of the upper electrodes UE1, UE2, and UE3 that are in contact with the side surfaces of the lower portion 61. A pixel voltage is supplied to the lower electrodes LE1, LE2, and LE3 through the pixel circuits 1 included in the respective sub-pixels SP1, SP2, and SP3.

The organic layers OR1, OR2, and OR3 emit light in response to application of the voltage. More specifically, when a potential difference is formed between the lower electrode LE1 and the upper electrode UE1, the light emitting layer of the organic layer OR1 emits light of the blue wavelength range. When a potential difference is formed between the lower electrode LE2 and the upper electrode UE2, the light emitting layer of the organic layer OR2 emits light of the green wavelength range. When a potential difference is formed between the lower electrode LE3 and the upper electrode UE3, the light emitting layer of the organic layer OR3 emits light of the red wavelength range.

As another example, the light emitting layers of the organic layers OR1, OR2, and OR3 may emit light of the same color (for example, white). In this case, the display device DSP may comprise color filters that convert the light emitted from the light emitting layers into light of the colors corresponding to the sub-pixels SP1, SP2, and SP3. In addition, the display device DSP may comprise a layer including quantum dots that are excited by the light emitted from the light emitting layers and generate the light of the colors corresponding to the sub-pixels SP1, SP2, and SP3.

When manufacturing the display device DSP, a large motherboard on which a plurality of areas (panel portions) each corresponding to a display panel PNL are formed, respectively, is formed. A configuration that can be applied to this motherboard will be described below.

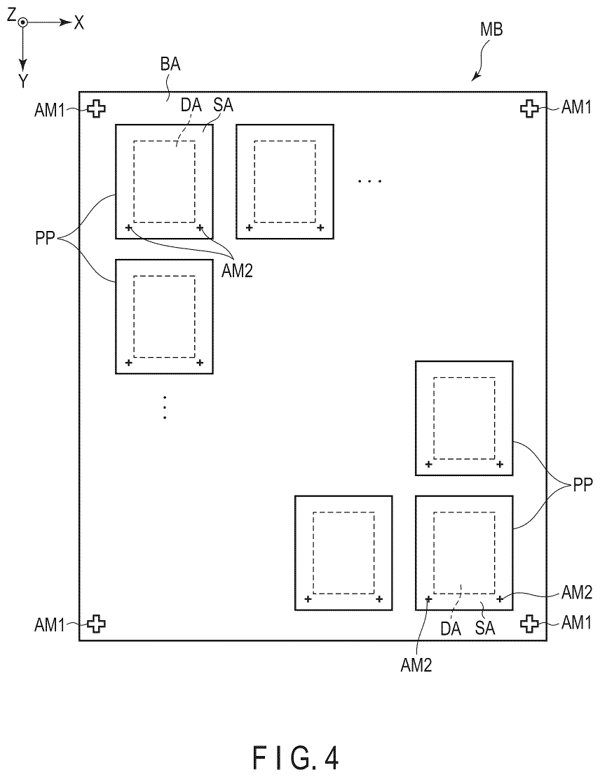

FIG. 4 is a schematic plan view showing a motherboard MB (motherboard for display device) according to the present embodiment. The motherboard MB has, for example, a rectangular shape as shown in the drawing, but may have other shapes such as a circular shape. The motherboard MB includes a plurality of panel portions PP arrayed in a matrix and a margin area BA around these panel portions PP. The margin area BA may be referred to as a blank area.

A plurality of first alignment marks AM1 are formed in the margin area BA. The first alignment marks AM1 include marks for alignment, marks for exposure, and the like. The first alignment marks AM1 are formed by, for example, the same manufacturing process using the same material as the signal lines SL included in the circuit layer 11. Incidentally, the first alignment marks AM1 may be formed by the same manufacturing process using the same material as the other lines and the other circuits included in the circuit layer 11. The first alignment marks AM1 are provided at, for example, four corners of the motherboard MB as shown in the drawing, but the number and arrangement of the first alignment marks AM1 provided on the motherboard MB are not limited to this example.

Each panel portion PP has the display area DA and the surrounding area SA as described above. A plurality of second alignment marks AM2 are formed in the surrounding area SA. The second alignment marks AM2 include marks for positioning, marks for exposure, and the like. The second alignment marks AM2 are formed by, for example, the same manufacturing process using the same material as the signal lines SL included in the circuit layer 11. Incidentally, the second alignment marks AM2 may be formed by the same manufacturing process using the same material as the other lines and the other circuits included in the circuit layer 11. The second alignment marks AM2 are provided in, for example, the mounting area (mounting side) where a flexible printed circuit and the like are mounted, in the surrounding area SA as shown in the drawing, but the number and arrangement of the second alignment marks AM2 provided on each panel portion PP are not limited to this example.

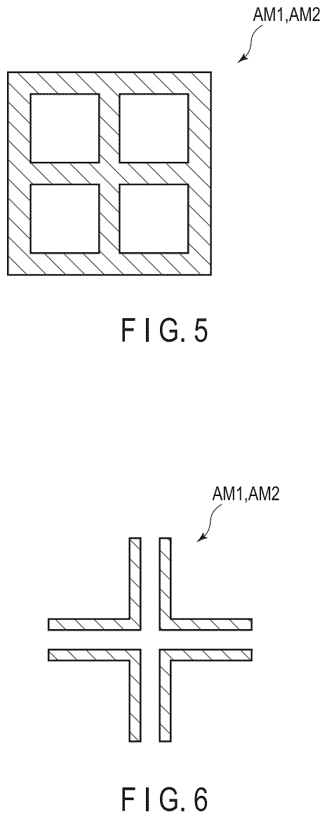

Incidentally, FIG. 4 shows a case in which the first alignment marks AM1 and the second alignment marks AM2 are formed in a cross shape, but the shape of the alignment marks AM1 and AM2 is not limited to this example. For example, the alignment marks AM1 and AM2 may have a grating shape as shown in FIG. 5. Alternatively, the alignment marks AM1 and AM2 may be a shape formed by combining a plurality of L-letter shapes as shown in FIG. 6. Incidentally, the first alignment marks AM1 and the second alignment marks AM2 may have the same shape as each other as shown in FIG. 4 or may have different shapes.

Next, a method of manufacturing the motherboard MB and the display device DSP will be described.

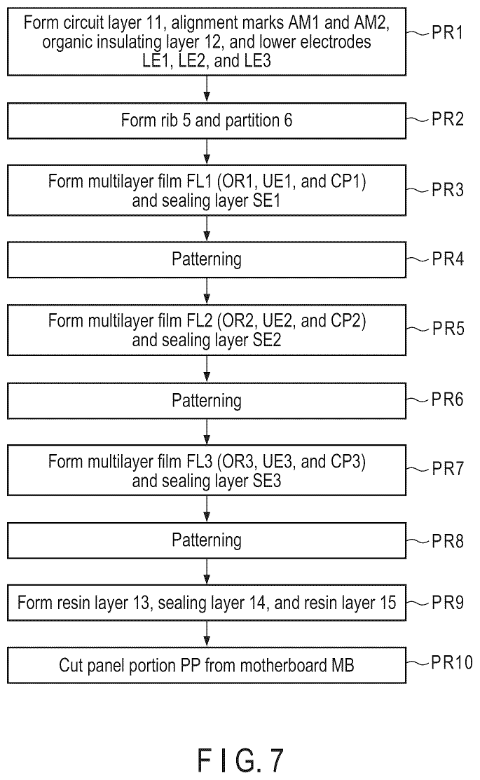

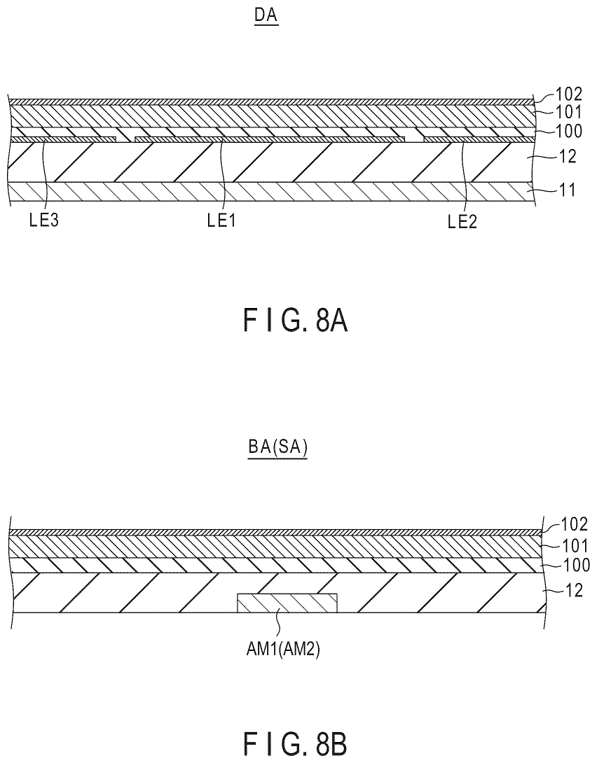

FIG. 7 is a flowchart showing an example of the method of manufacturing the motherboard MB and the display device DSP. Each of FIG. 8A to FIG. 15A is a schematic cross-sectional view showing the display area DA in the motherboard MB during the manufacturing process. Each of FIG. 8B to FIG. 15B is a schematic cross-sectional view showing the margin area BA in the motherboard MB during the manufacturing process. The same manufacturing processes as FIG. 8B to FIG. 15B can also be applied to the surrounding area SA. Incidentally, the substrate 10 is omitted in FIG. 8A to FIG. 15A and FIG. 8B to FIG. 15B.

In manufacturing the display device DSP, the circuit layer 11, the alignment marks AM1 and AM2, the organic insulating layer 12, and the lower electrodes LE1, LE2, and LE3 are first formed on the substrate 10 (process PR1). Furthermore, the rib 5 and the partition 6 are formed (process PR2).

In process PR1, the alignment marks AM1 and AM2 are formed of the same material, by the same manufacturing process, as any lines or circuits included in the circuit layer 11, as shown in FIG. 8B, in the margin area BA and the surrounding area SA. Also, the organic insulating layer 12 is formed over the entire motherboard MB as shown in FIG. 8A and FIG. 8B. In other words, the organic insulating layer 12 extends from the display area DA to the margin area BA and the surrounding area SA. In process PR2, an inorganic insulating layer 100 which is to be processed into the rib 5 is formed over the entire motherboard MB as shown in FIG. 8A and FIG. 8B. In other words, the inorganic insulating layer 100 is also arranged in positions overlapping with the alignment marks AM1 and AM2 in plan view, and covers the organic insulating layer 12. Furthermore, a first layer 101 which is to be processed into the lower portion 61 is formed on the inorganic insulating layer 100, and a second layer 102 which is to be processed into the upper portion 62 is formed on the first layer 101.

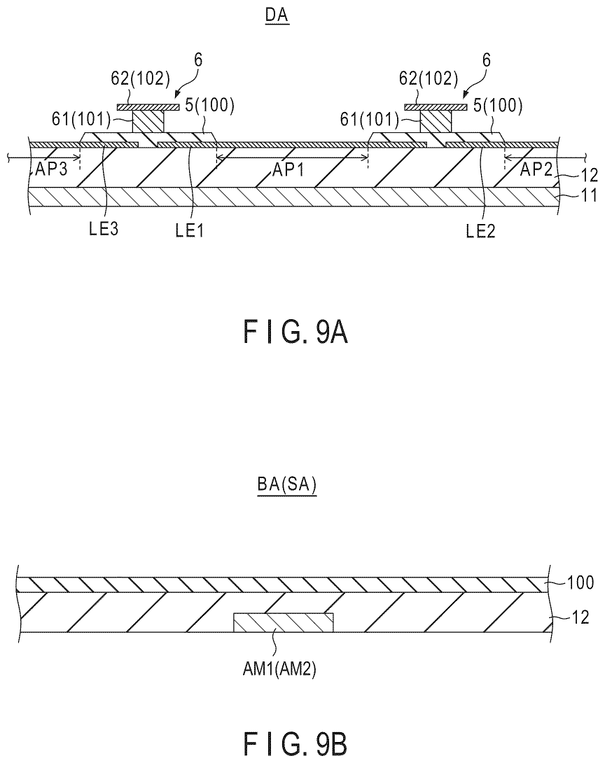

Next, the first layer 101 and the second layer 102 are patterned as shown in FIG. 9A. This patterning includes etching to process the second layer 102 into the shape of the upper portion 62 and etching to process the first layer 101 into the shape of the lower portion 61. The partition 6 including the lower portion 61 and the upper portion 62 is formed in the display area DA by the etching. Incidentally, the margin area BA and the surrounding area SA are also subjected to the above-described etching. Therefore, the first layer 101 and the second layer 102 are removed from the margin area BA and the surrounding area SA, as shown in FIG. 9B.

After the formation of the partition 6, the pixel apertures AP1, AP2, and AP3 are formed in the inorganic insulating layer 100, as shown in FIG. 9A. The rib 5 is thereby formed in the display area DA. Incidentally, FIG. 8A and FIG. 9A show the case where the pixel apertures AP1, AP2, and AP3 are formed after the partition 6 is formed, but the partition 6 may be formed after the pixel apertures AP1, AP2, and AP3 are formed as another example.

After the formation of the rib 5 and the partition 6, a process for forming the display elements DE1, DE2, and DE3 is carried out. In the present embodiment, it is assumed that the display element DE1 is first formed, then the display element DE2 is formed, and the display element DE3 is formed last. However, the order of formation of the display elements DE1, DE2, and DE3 is not limited to this example.

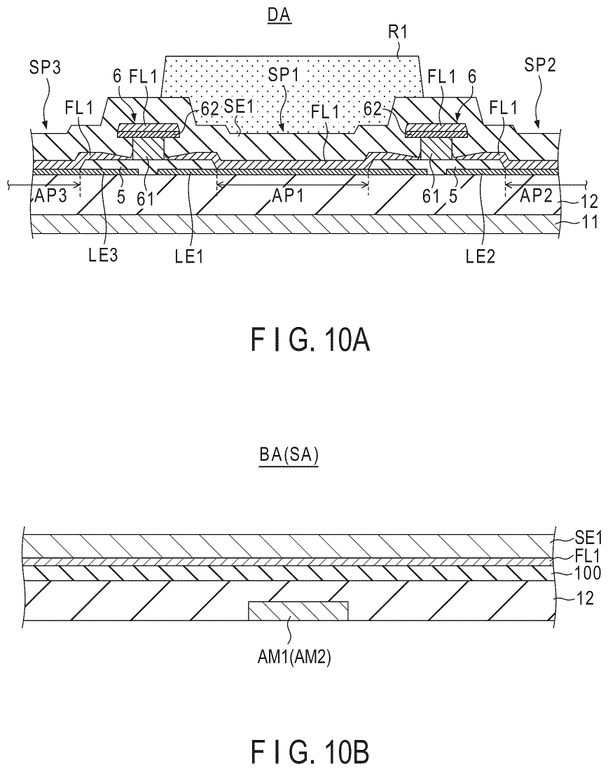

In forming the display element DE1, first, the multilayer film FL1 and the sealing layer SE1 are formed on the entire motherboard MB as shown in FIG. 10A and FIG. 10B (process PR3). The multilayer film FL1 includes the organic layer OR1 which is in contact with the lower electrode LE1 through the pixel aperture AP1, the upper electrode UE1 which covers the organic layer OR1, and the cap layer CP1 which covers the upper electrode UE1, as shown in FIG. 3. The organic layer OR1, the upper electrode UE1, and the cap layer CP1 are formed by vapor deposition. In addition, the sealing layer SE1 is formed by chemical vapor deposition (CVD).

The multilayer film FL1 is divided into a plurality of parts by the overhanging partition 6. As shown in FIG. 10A, the multilayer film FL1 in the display area DA covers the lower electrodes LE1, LE2, and LE3, the rib 5, and the partition 6 exposed through the pixel apertures AP1, AP2, and AP3. In addition, as shown in FIG. 10B, the multilayer film FL1 in the margin area BA and the surrounding area SA covers the inorganic insulating layer 100.

As shown in FIG. 10A, the sealing layer SE1 in the display area DA continuously covers each of the divided parts of the multilayer film FL1 and the partition 6. In addition, as shown in FIG. 10B, the sealing layer SE1 in the margin area BA and the surrounding area SA covers the multilayer film FL1.

After process PR3, the multilayer film FL1 and the sealing layer SE1 are patterned (process PR4). In the patterning, a resist R1 is arranged on the sealing layer SE1 as shown in FIG. 10A. The resist R1 covers the sub-pixel SP1 and a part of the partition 6 surrounding the sub-pixel SP1. The resist R1 is not arranged in the margin area BA or the surrounding area SA.

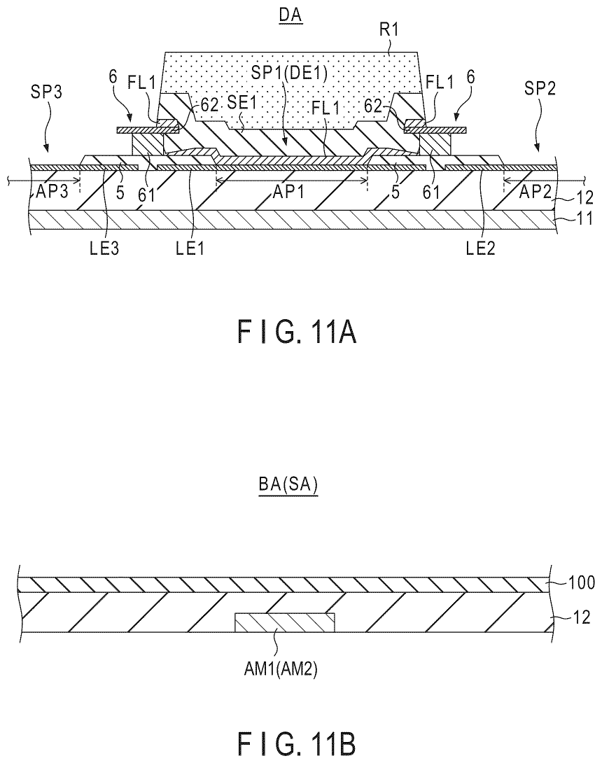

After that, the parts of the multilayer film FL1 and the sealing layer SE1, which are exposed from the resist R1, are removed as shown in FIG. 11A, by etching using the resist R1 as a mask. The display element DE1 is thereby formed in the sub-pixel SP1. For example, the etching includes wet etching and dry etching performed sequentially for the sealing layer SE1, the cap layer CP1, the upper electrode UE1, and the organic layer OR1.

The margin area BA and the surrounding area SA are also subjected to the etching. Therefore, the multilayer film FL1 and the sealing layer SE1 arranged in the margin area BA and the surrounding area SA are removed as shown in FIG. 11B. As described above, the etching is performed sequentially on the sealing layer SE1, the cap layer CP1, the upper electrode UE1, and the organic layer OR1, and the inorganic insulating layer 100 is not removed and remains as it is since the etching finally performed on the organic layer OR1 does not affect the inorganic insulating layer 100. For this reason, the organic insulating layer 12 and the alignment marks AM1 and AM2, which are arranged below the inorganic insulating layer 100, are not removed and remain as they are as well. After the etching, the resist R1 is removed.

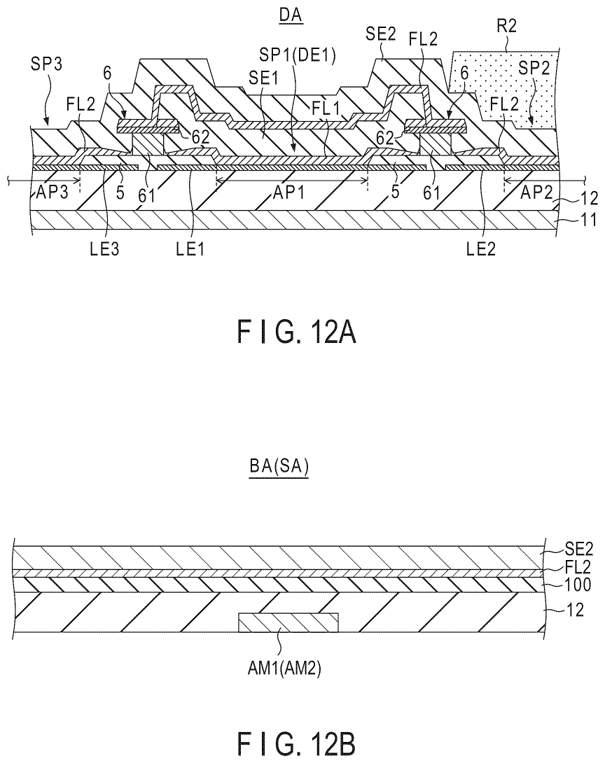

The display element DE2 is formed in the same procedure as the display element DE1. In other words, in forming the display element DE2, first, the multilayer film FL2 and the sealing layer SE2 are formed on the entire motherboard MB as shown in FIG. 12A and FIG. 12B (process PR5). The multilayer film FL2 includes the organic layer OR2 which is in contact with the lower electrode LE2 through the pixel aperture AP2, the upper electrode UE2 which covers the organic layer OR2, and the cap layer CP2 which covers the upper electrode UE2, as shown in FIG. 3. The organic layer OR2, the upper electrode UE2, and the cap layer CP2 are formed by vapor deposition. In addition, the sealing layer SE2 is formed by CVD.

As shown in FIG. 12A, the multilayer film FL2 in the display area DA is divided into a plurality of parts by the overhanging partition 6, and the sealing layer SE2 in the display area DA continuously covers each of the divided parts of the multilayer film FL2 and the partition 6. In contrast, as shown in FIG. 12B, the multilayer film FL2 in the margin area BA and the surrounding area SA covers the inorganic insulating layer 100, and the sealing layer SE2 in the margin area BA and the surrounding area SA covers the multilayer film FL2.

After process PR5, the multilayer film FL2 and the sealing layer SE2 are patterned (process PR6). In the patterning, a resist R2 is arranged on the sealing layer SE2 as shown in FIG. 12A. The resist R2 covers the sub-pixel SP2 and a part of the partition 6 surrounding the sub-pixel SP2. The resist R2 is not arranged in the margin area BA or the surrounding area SA.

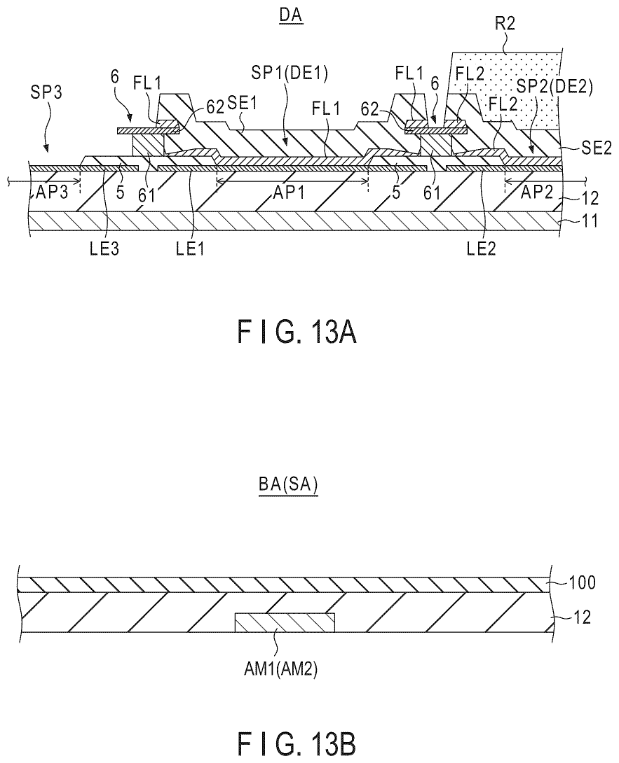

After that, the parts of the multilayer film FL2 and the sealing layer SE2, which are exposed from the resist R2, are removed as shown in FIG. 13A, by etching using the resist R2 as a mask. The display element DE2 is thereby formed in the sub-pixel SP2. For example, the etching includes wet etching and dry etching performed sequentially for the sealing layer SE2, the cap layer CP2, the upper electrode UE2, and the organic layer OR2.

The margin area BA and the surrounding area SA are also subjected to the etching. Therefore, the multilayer film FL2 and the sealing layer SE2 arranged in the margin area BA and the surrounding area SA are removed as shown in FIG. 13B. As described above, the etching is performed sequentially on the sealing layer SE2, the cap layer CP2, the upper electrode UE2, and the organic layer OR2, and the inorganic insulating layer 100 is not removed and remains as it is since the etching finally performed on the organic layer OR2 does not affect the inorganic insulating layer 100. For this reason, the organic insulating layer 12 and the alignment marks AM1 and AM2, which are arranged below the inorganic insulating layer 100, are not removed and remain as they are as well. After the etching, the resist R2 is removed.

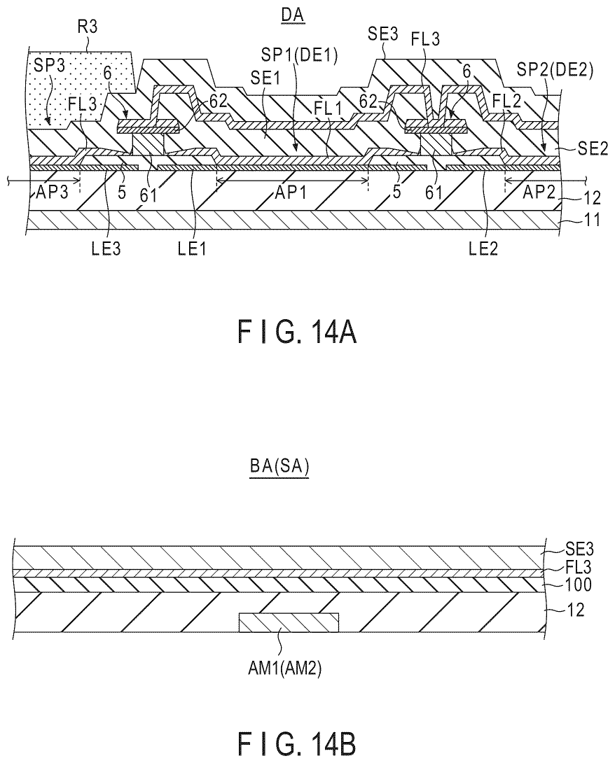

The display element DE3 is formed in the same procedure as the display elements DE1 and DE2. In other words, in forming the display element DE3, first, the multilayer film FL3 and the sealing layer SE3 are formed on the entire motherboard MB as shown in FIG. 14A and FIG. 14B (process PR7). The multilayer film FL3 includes the organic layer OR3 which is in contact with the lower electrode LE3 through the pixel aperture AP3, the upper electrode UE3 which covers the organic layer OR3, and the cap layer CP3 which covers the upper electrode UE3, as shown in FIG. 3. The organic layer OR3, the upper electrode UE3, and the cap layer CP3 are formed by vapor deposition. In addition, the sealing layer SE3 is formed by CVD.

As shown in FIG. 14A, the multilayer film FL3 in the display area DA is divided into a plurality of parts by the overhanging partition 6, and the sealing layer SE3 in the display area DA continuously covers each of the divided parts of the multilayer film FL3 and the partition 6. In contrast, as shown in FIG. 14B, the multilayer film FL3 in the margin area BA and the surrounding area SA covers the inorganic insulating layer 100, and the sealing layer SE3 in the margin area BA and the surrounding area SA covers the multilayer film FL3.

After process PR7, the multilayer film FL3 and the sealing layer SE3 are patterned (process PR8). In the patterning, a resist R3 is arranged on the sealing layer SE3 as shown in FIG. 14A. The resist R3 covers the sub-pixel SP3 and a part of the partition 6 surrounding the sub-pixel SP3. The resist R3 is not arranged in the margin area BA or the surrounding area SA.

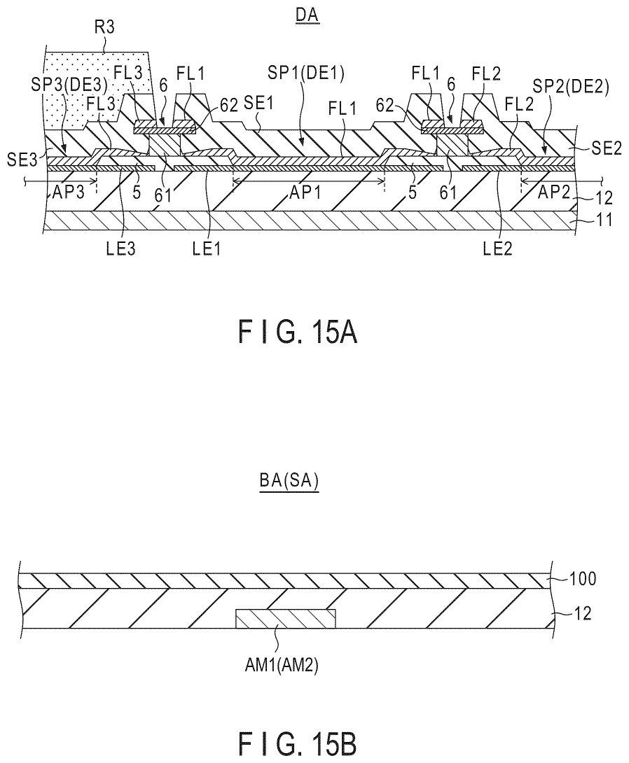

After that, the parts of the multilayer film FL3 and the sealing layer SE3, which are exposed from the resist R3, are removed as shown in FIG. 15A, by etching using the resist R3 as a mask. The display element DE3 is thereby formed in the sub-pixel SP3. For example, the etching includes wet etching and dry etching performed sequentially for the sealing layer SE3, the cap layer CP3, the upper electrode UE3, and the organic layer OR3.

The margin area BA and the surrounding area SA are also subjected to the etching. Therefore, the multilayer film FL3 and the sealing layer SE3 arranged in the margin area BA and the surrounding area SA are removed as shown in FIG. 15B. As described above, the etching is performed sequentially on the sealing layer SE3, the cap layer CP3, the upper electrode UE3, and the organic layer OR3, and the inorganic insulating layer 100 is not removed and remains as it is since the etching finally performed on the organic layer OR3 does not affect the inorganic insulating layer 100. For this reason, the organic insulating layer 12 and the alignment marks AM1 and AM2, which are arranged below the inorganic insulating layer 100, are not removed and remain as they are as well. After the etching, the resist R3 is removed.

After the display elements DE1, DE2, and DE3 are formed, the resin layer 13, the sealing layer 14, and the resin layer 15 shown in FIG. 3 are formed sequentially for each panel portion PP (process PR9). Furthermore, each panel portion PP is cut out from the motherboard MB (process PR10). The cut panel portion PP corresponds to the display panel PNL.

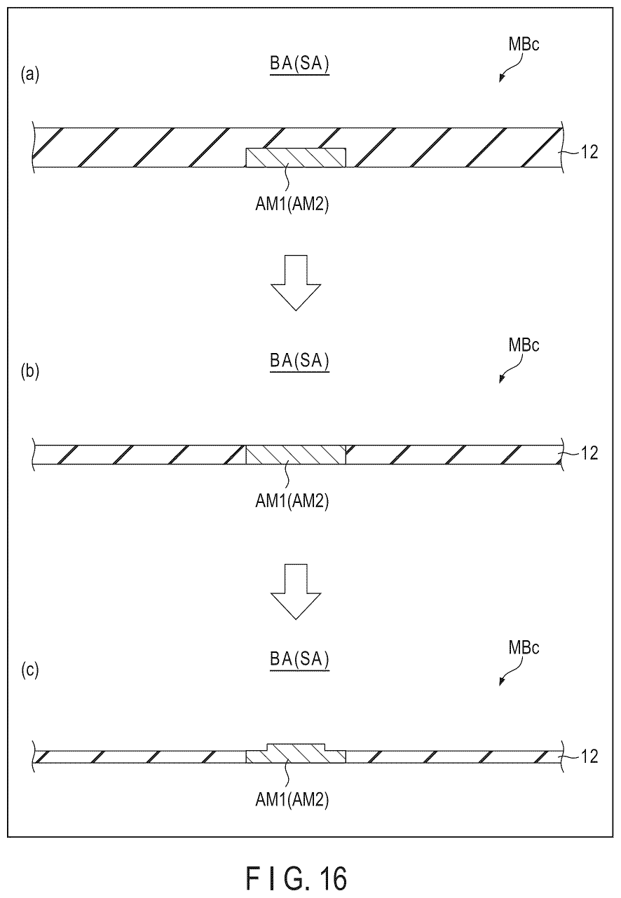

According to the display device DSP and the motherboard MB according to the present embodiment, the disappearance or smudge of the alignment marks AM1 and AM2 can be suppressed. This effect will be described below with reference to FIG. 16.

FIG. 16 is a schematic cross-sectional view showing a margin area BA (or the surrounding area SA) of a motherboard MBc according to a comparative example. The motherboard MBc is different from the motherboard MB according to the present embodiment in that the organic insulating layer 12 is not covered with the inorganic insulating layer 100.

The cross section in FIG. 16 (a) corresponds to the same process as the process in FIG. 11B, and the organic insulating layer 12 is shaved off by the etching (wet etching or dry etching) performed to remove the multilayer film FL1 and the sealing layer SE1 arranged in the margin area BA and the surrounding area SA. In addition, the cross section in FIG. 16 (b) corresponds to the same process as the process in FIG. 13B, and the organic insulating layer 12 is further shaved off by the etching (wet etching or dry etching) performed to remove the multilayer film FL2 and the sealing layer SE2 arranged in the margin area BA and the surrounding area SA, and the surfaces of the alignment marks AM1 and AM2 are exposed. Furthermore, the cross section in FIG. 16 (c) corresponds to the same process as the process in FIG. 15B, and not only the organic insulating layer 12, but the alignment marks AM1 and AM2 are shaved off by the etching (wet etching or dry etching) performed to remove the multilayer film FL3 and the sealing layer SE3 arranged in the margin area BA and the surrounding area SA, and the shapes of the alignment marks AM1 and AM2 are changed.

As shown in FIG. 16, in the motherboard MBc according to the comparative example, the organic insulating layer 12 arranged in the margin area BA and the surrounding area SA is gradually shaved off by the etching repeatedly performed in the process to form the display elements DE1, DE2, and DE3. As a result, as shown in FIG. 16 (b), the surfaces of the alignment marks AM1 and AM2 may be exposed from the organic insulating layer 12 which protects the alignment marks AM1 and AM2. If the surfaces of alignment marks AM1 and AM2 are exposed from the organic insulating layer 12, the alignment marks AM1 and AM2 may be smudged when the motherboard MBc is subjected to a cleaning process or a development process. In addition, in the motherboard MBc according to the comparative example, as shown in FIG. 16 (c), the alignment marks AM1 and AM2 may be shaved off together with the organic insulating layer 12 and may be deformed in shape or even disappear. If the alignment marks AM1 and AM2 are lost or smudged, positioning cannot be accurately performed.

In contrast, in the motherboard MB according to the present embodiment, since the inorganic insulating layer 100 for processing into the rib 5 is arranged not only in the display area DA but also in the margin area BA and the surrounding area SA, the organic insulating layer 12 can be protected from etching which is repeatedly performed in the process to form the display elements DE1, DE2, and DE3. According to this, since the alignment marks AM1 and AM2, which are arranged below the organic insulating layer 12, can also be protected from the above-described etching, the disappearance or smudge of the alignment marks AM1 and AM2 can be suppressed.

According to one embodiment described above, the motherboard MB and the display device DSP capable of suppressing the disappearance or smudge of the alignment marks AM1 and AM2 can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A motherboard for display device, comprising:
a plurality of panel portions each including a display area where a plurality of display elements are arranged;
a margin area around the plurality of panel portions; and
an alignment mark arranged in the margin area, wherein
the panel portion includes an organic insulating layer, a lower electrode arranged above the organic insulating layer, an upper electrode opposed to the lower electrode, and an organic layer arranged between the lower electrode and the upper electrode to emit light in accordance with a potential difference between the lower electrode and the upper electrode,
the organic insulating layer extends from the display area to the margin area, and
the organic insulating layer arranged in the margin area and an inorganic insulating layer covering the organic insulating layer are arranged above the alignment mark.

2. The motherboard for display device of claim 1, wherein
the panel portion further includes a rib including a pixel aperture which overlaps with the lower electrode, and
the rib and the inorganic insulating layer are formed of the same inorganic insulating material.

3. The motherboard for display device of claim 2, wherein
the panel portion further includes a partition arranged above the rib, and
the partition is connected to the upper electrode.

4. The motherboard for display device of claim 1, wherein
the panel portion further includes a circuit layer arranged under the organic insulating layer, and
the alignment mark is formed of the same conductive material as a wire included in the circuit layer.

5. The motherboard for display device of claim 1, wherein
the alignment mark is formed in a cross shape, a grating shape, or a shape formed by combining a plurality of L letters, in plan view.

6. The motherboard for display device of claim 1, wherein
the panel portion further includes a surrounding area around the display area, and
the alignment marks are arranged in the margin area and the surrounding area.

7. A display device comprising:
a display area where a plurality of display elements are arranged;
a surrounding area around the display area; and
an alignment mark arranged in the surrounding area, wherein
an organic insulating layer, a lower electrode arranged above the organic insulating layer, an upper electrode opposed to the lower electrode, and an organic layer arranged between the lower electrode and the upper electrode to emit light in accordance with a potential difference between the lower electrode and the upper electrode, are provided in the display area,
the organic insulating layer extends from the display area to the surrounding area, and
the organic insulating layer arranged in the surrounding area and an inorganic insulating layer covering the organic insulating layer are arranged above the alignment mark.

8. The display device of claim 7, wherein
a rib including a pixel aperture which overlaps with the lower electrode is further provided in the display area, and
the rib and the inorganic insulating layer are formed of the same inorganic insulating material.

9. The display device of claim 8, wherein
a partition arranged above the rib is provided in the display area, and
the partition is connected to the upper electrode.

10. The display device of claim 7, wherein
a circuit layer arranged under the organic insulating layer is further provided in the display area, and
the alignment mark is formed of the same conductive material as a wire included in the circuit layer.

11. The display device of claim 7, wherein
the alignment mark is formed in a cross shape, a grating shape, or a shape formed by combining a plurality of L letters, in plan view.
